(19) United States
(12) Patent Application Publication
(10) Pub. No.: US 2025/0287597 A1
(43) Pub. Date: Sep. 11, 2025

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Donghun SIN, Suwon-si (KR); Euijoong SHIN, Daejeon (KR); Byungjin CHO, Daejeon (KR); Hanmei CHOI, Suwon-si (KR); Bio KIM, Suwon-si (KR); Philouk NAM, Suwon-si (KR)

(73) Assignees: Samsung Electronics Co., Ltd., Suwon-si (KR); KOREA ADVANCED INSTITUTE OF SCIENCE AND TECHNOLOGY, Daejeon (KR)

(21) Appl. No.: 18/887,200

(22) Filed: Sep. 17, 2024

(30) Foreign Application Priority Data
Mar. 11, 2024 (KR) 10-2024-0033956

(51) Int. Cl. H10B 43/35; H10B 43/27

(52) U.S. Cl. CPC H10B 43/35; H10B 43/27

(57) ABSTRACT

A semiconductor device includes a plate layer, gate electrodes on the plate layer, spaced apart from each other in a first direction, and including channel holes passing therethrough and extending in the first direction, and channel structures in the channel holes each of the channel structures including a blocking layer, a charge storage structure, a tunneling layer, and a channel layer, sequentially arranged from the gate electrodes in a second direction, wherein the charge storage structure has a first region adjacent to the tunneling layer and a second region between the first region and the blocking layer, the charge storage structure includes charge trap layers including silicon nitride and barrier layers between the charge trap layers and including a two-dimensional insulating material, and a density of the barrier layers in the first region is relatively high than a density thereof in the second region.

### CROSS-REFERENCE TO RELATED APPLICATION(S)

This application claims benefit of priority to Korean Patent Application No. 10-2024-0033956 filed on Mar. 11, 2024 in the Korean Intellectual Property Office, the disclosure of which is incorporated herein by reference in its entirety.

### BACKGROUND

The present inventive concept relates to a semiconductor device and a data storage system including the same.

In a data storage system requiring data storage, a semiconductor device for storing high-capacity data may be required. Accordingly, methods for increasing data storage capacity of semiconductor devices are being researched. For example, as a method for increasing data storage capacity of a semiconductor device, a semiconductor device including memory cells arranged three-dimensionally, instead of memory cells arranged two-dimensionally, has been proposed.

### SUMMARY

Some example embodiments of the present disclosure provide semiconductor devices having improved electrical characteristics and reliability.

Some example embodiments of the present disclosure provide data storage systems including a semiconductor device having improved electrical characteristics and reliability.

According to an example embodiment of the present disclosure, a semiconductor device includes a plate layer, gate electrodes stacked on the plate layer, the gate electrodes spaced apart from each other in a first direction, the first direction being perpendicular to an upper surface of the plate layer, the gate electrodes including channel holes passing therethrough and extending in the first direction, and channel structures in the channel holes, each of the channel structures including a blocking layer, a charge storage structure, a tunneling layer, a channel layer, and a buried channel insulating layer that are sequentially arranged from the gate electrodes in a second direction, the second direction being perpendicular to the first direction, wherein the charge storage structure has a first region adjacent to the tunneling layer, a second region between the first region and the blocking layer, and a third region between the second region and the blocking layer, the charge storage structure includes charge trap layers and barrier layers between the charge trap layers, and the barrier layers have a first thickness in the first region and a second thickness in the second region, the second thickness being less than the first thickness, and the barrier layers are absent in the third region.

According to an example embodiment of the present disclosure, a semiconductor device includes a plate layer, gate electrodes stacked on the plate layer, the gate electrodes spaced apart from each other in a first direction, the first direction being perpendicular to an upper surface of the plate layer, the gate electrodes including channel holes passing therethrough and extending in the first direction, and channel structures in the channel holes, each of the channel structures including a blocking layer, a charge storage structure, a tunneling layer, and a channel layer that are sequentially arranged from the gate electrodes in a second direction, the second direction being perpendicular to the first direction, wherein the charge storage structure has a first region adjacent to the tunneling layer and a second region between the first region and the blocking layer, the charge storage structure includes charge trap layers and barrier layers between the charge trap layers, the charge trap layers including silicon nitride, the barrier layers including a two-dimensional insulating material, and the barrier layers are arranged at a first density in the first region and at a second density in the second region, the second density being lower than the first density.

According to an example embodiment of the present disclosure, a data storage system includes a semiconductor storage device including a first semiconductor structure including circuit elements, a second semiconductor structure on the first semiconductor structure, and an input/output pad electrically connected to the circuit elements, and a controller electrically connected to the semiconductor storage device through the input/output pad and configured to control the semiconductor storage device, wherein the second semiconductor structure includes a plate layer, gate electrodes stacked on the plate layer, the gate electrodes spaced apart from each other in a first direction, the first direction being perpendicular to an upper surface of the plate layer, the gate electrodes including channel holes passing therethrough and extending in the first direction, and channel structures in the channel holes, each of the channel structures including a blocking layer, a charge storage structure, a tunneling layer, and a channel layer that are sequentially arranged from the gate electrodes in a second direction, the second direction being perpendicular to the first direction, wherein the charge storage structure has a first region adjacent to the tunneling layer and a second region between the first region and the blocking layer, the charge storage structure includes charge trap layers and barrier layers between the charge trap layers, the charge trap layers including silicon nitride, the barrier layers including a two-dimensional insulating material, and the barrier layers are arranged at a first density in the first region and at a second density in the second region, the second density being lower than the first density.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic plan view of a semiconductor device according to an example embodiment.

FIG. 2 is a schematic cross-sectional view of a semiconductor device according to an example embodiment 1.

FIGS. 3A and 3B are schematic partially enlarged views of a semiconductor device according to some example embodiments.

FIG. 4 is a schematic partially enlarged view of a semiconductor device according to an example embodiment.

FIG. 5 is a view illustrating a semiconductor device according to an example embodiment.

FIG. 6 is a view illustrating a semiconductor device according to an example embodiment.

FIGS. 7A to 7E are schematic partially enlarged views of semiconductor devices according to some example embodiments.

FIG. 8 is a cross-sectional view illustrating a semiconductor device according to an example embodiment.

FIGS. 9A and 9B are schematic cross-sectional views of semiconductor devices according to some example embodiments.

FIGS. 10A to 10D are schematic cross-sectional views illustrating a method of manufacturing a semiconductor device according to an example embodiment.

FIG. 11 is a view illustrating a method of manufacturing a semiconductor device according to an example embodiment.

FIG. 12 is a view schematically illustrating a data storage system including a semiconductor device according to an example embodiment.

FIG. 13 is a perspective view schematically illustrating a data storage system including a semiconductor device according to an example embodiment.

FIG. 14 is a cross-sectional view schematically illustrating a semiconductor package according to an example embodiment.

### DETAILED DESCRIPTION

Hereinafter, some example embodiments of the present inventive concepts will be described with reference to the attached drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the term “about,” “substantially” or “approximately” is used in this specification in connection with a numerical value, it is intended that the associated numerical value includes a manufacturing or operational tolerance (e.g., +10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

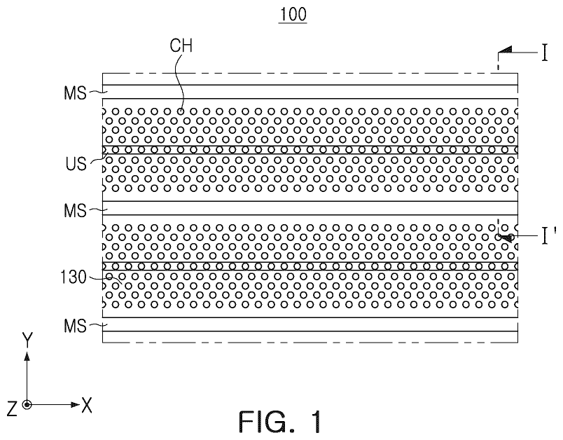

FIG. 1 is a schematic plan view of a semiconductor device according to an example embodiment.

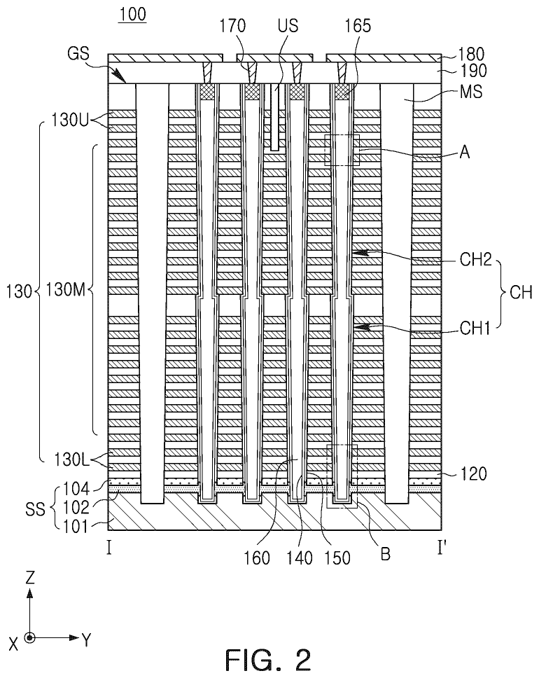

FIG. 2 is a schematic cross-sectional view of a semiconductor device according to an example embodiment. FIG. 2 illustrates a cross-section of FIG. 1, taken along line I-I′.

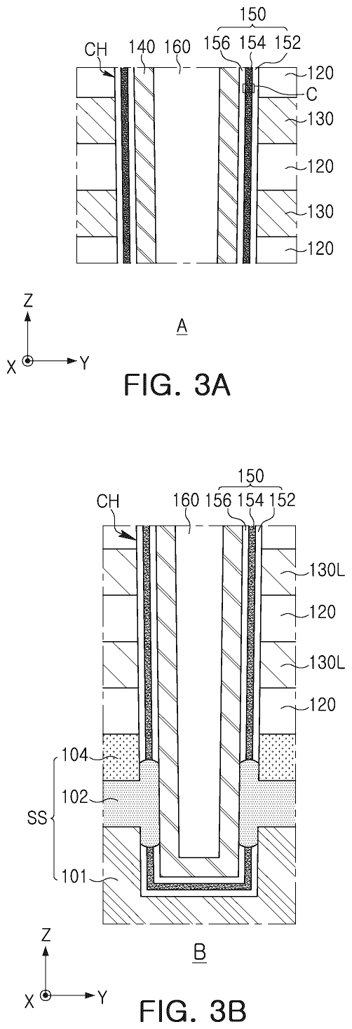

FIGS. 3A and 3B are schematic partially enlarged views of a semiconductor device according to some example embodiments. FIG. 3A illustrates an enlarged view of portion ‘A’ of FIG. 2, and FIG. 3B illustrates an enlarged view of portion ‘B’ of FIG. 2.

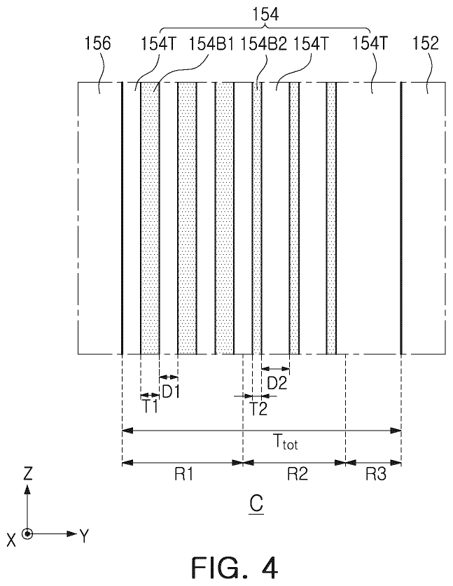

FIG. 4 is a schematic partially enlarged view of a semiconductor device according to an example embodiment. FIG. 4 illustrates an enlarged view of portion ‘C’ of FIG. 3A.

Referring to FIGS. 1 to 4, a semiconductor device 100 may include a source structure SS including a plate layer 101 and first and second horizontal conductive layers 102 and 104 on the plate layer 101, gate electrodes 130 stacked on the plate layer 101, interlayer insulating layers 120 alternately stacked with the gate electrodes 130 on the plate layer 101, channel structures CH arranged to pass through the gate electrodes 130, first separation regions MS extending through the gate electrodes 130, second separation regions US passing through upper gate electrodes 130U among the gate electrodes 130, a cell region insulating layer 190 on the channel structures CH, studs 170 connected to the channel structures CH, respectively, and bit lines 180 on the studs 170.

The source structure SS may include the plate layer 101, the first horizontal conductive layer 102, and the second horizontal conductive layer 104, sequentially stacked. In example embodiments, the number of conductive layers forming the source structure SS may be changed.

The plate layer 101 may have a shape of a plate, and may function as at least a portion of a common source line of the semiconductor device 100. The plate layer 101 may have an upper surface extending in X-direction and Y-direction. The plate layer 101 may include a conductive material. For example, the plate layer 101 may include a semiconductor material, such as a group IV semiconductor, a group III-V compound semiconductor, or a group II-VI compound semiconductor. For example, the group IV semiconductors may include silicon, germanium, or silicon-germanium. The plate layer 101 may further include impurities. The plate layer 101 may be provided as a polycrystalline semiconductor layer such as a polycrystalline silicon layer, or an epitaxial layer.

The first and second horizontal conductive layers 102 and 104 may be sequentially stacked and disposed on the upper surface of the plate layer 101. The first horizontal conductive layer 102 may function as a portion of the common source line of the semiconductor device 100, for example, may function as the common source line, together with the plate layer 101. As illustrated in FIG. 3B, the first horizontal conductive layer 102 may be directly connected to a channel layer 140 around the channel layer 140. The first and second horizontal conductive layers 102 and 104 may include a semiconductor material, for example, polycrystalline silicon.

The gate electrodes 130 may be vertically spaced apart and stacked on the plate layer 101, to form a stack structure GS, together with the interlayer insulating layers 120. The stack structure GS may include lower and upper stack structures, vertically stacked. Depending on some example embodiments, the stack structure GS may be provided as a single stack structure. The gate electrodes 130 include lower gate electrodes 130L forming gates of a ground select transistor, memory gate electrodes 130M forming gates of a plurality of memory cells, and upper gate electrodes 130U forming gates of string select transistors. The number of memory gate electrodes 130M forming memory cells may be determined according to the capacity of the semiconductor device 100. The upper gate electrode 130U and the lower gate electrodes 130L may also be referred to as an upper selection gate electrode and a lower selection gate electrode, respectively. Depending on some example embodiments, the number of upper and lower gate electrodes 130U and 130L may be one to four or more, respectively, and may have the same or different structure as the memory gate electrodes 130M. In some example embodiments, the gate electrodes 130 may further include a gate electrode disposed on one side of the upper gate electrodes 130U and/or one side of the lower gate electrodes 130L, and forming an erase transistor used in an erase operation using a gate induced leakage (GIDL) phenomenon. Additionally, a portion of the gate electrodes 130, for example, memory gate electrodes 130M adjacent to the upper or lower gate electrodes 130U and 130L, may be dummy gate electrodes.

The gate electrodes 130 may include a metal material, for example, tungsten (W). Depending on some example embodiments, the gate electrodes 130 may include polycrystalline silicon or a metal silicide material. In some example embodiments, the gate electrodes 130 may further include a diffusion barrier, and, for example, the diffusion barrier may include tungsten nitride (WN), tantalum nitride (TaN), titanium nitride (TiN), or a combination thereof.

The interlayer insulating layers 120 may be alternately arranged with the gate electrodes 130. Like the gate electrodes 130, the interlayer insulating layers 120 may also be arranged to be spaced apart from each other in a direction, perpendicular to the upper surface of the plate layer 101. A portion of the interlayer insulating layers 120 may have different thicknesses. For example, an interlayer insulating layer 120 disposed adjacent to a region in which a first channel structure CH1 and a second channel structure CH2 are connected, and an interlayer insulating layer 120 on the uppermost upper gate electrode 130U may have a relatively large thickness. In example embodiments, a thickness of each of the interlayer insulating layers 120 may be changed. The interlayer insulating layers 120 may include an insulating material such as silicon oxide or silicon nitride.

The channel structures CH may be disposed in channel holes extending in a Z-direction (e.g., the direction perpendicular to the upper surface of the plate layer 101) through the stack structure GS, and may be connected to the plate layer 101. The channel structures CH may form memory cell strings, respectively, and may be arranged in rows and columns on the plate layer 101 to be spaced apart from each other. As illustrated in FIG. 1, the channel structures CH may be arranged to form a grid pattern in an X-Y plane or may be arranged in a zigzag shape in one direction. The channel structures CH have a pillar shape, and may have an inclined side surface narrowing toward the plate layer 101.

The channel structures CH may include the first and second channel structures CH1 and CH2, vertically stacked. The channel structures CH may have a shape in which the first channel structures CH1 and the second channel structures CH2 are connected, and may have a bent portion due to a difference in width in the connection region. Depending on example embodiments, the number of channel structures stacked in the Z-direction may be changed. Each of the channel structures CH may include a channel dielectric layer 150, a channel layer 140, and a buried channel insulating layer 160, sequentially arranged from the gate electrodes 130, as illustrated in FIGS. 3A and 3B, and may further include a channel pad 165 disposed on an upper end.

The channel layer 140 may be formed in an annular shape surrounding the buried channel insulating layer 160 therein, but depending on some example embodiments, may have a pillar shape such as a cylinder or prism without the buried channel insulating layer 160. The channel layer 140 may be connected to the first horizontal conductive layer 102 at a lower portion. The channel layer 140 may include a semiconductor material such as polycrystalline silicon or single crystalline silicon.

The channel dielectric layer 150 may be disposed between the gate electrodes 130 and the channel layer 140. The channel dielectric layer 150 may be disposed to cover inner side and bottom surfaces of the channel hole. The channel dielectric layer 150 may include a blocking layer 152, a charge storage structure 154, and a tunneling layer 156, sequentially stacked from the gate electrodes 130. In example embodiments, relative thicknesses of the blocking layer 152, the charge storage structure 154, and the tunneling layer 156 may be changed. In some example embodiments, the channel dielectric layer 150 may further include a horizontal blocking layer disposed between the blocking layer 152 and the gate electrodes 130 and extending in a horizontal direction along the gate electrodes 130.

The blocking layer 152 may include at least one of silicon oxide (SiO₂), silicon nitride (Si₃N₄), silicon oxynitride (SiON), or a high-K material. In this case, the high-K material refers to a dielectric material having a higher dielectric constant than silicon dioxide (SiO₂). The high-K material may include, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), praseodymium oxide (Pr₂O₃), or a combination thereof.

The tunneling layer 156 may tunnel charges into the charge storage structure 154 using a Fowler Nordheim tunneling (FN tunneling) manner, and may include, for example, at least one of silicon oxide (SiO₂), silicon nitride (Si₃N₄), silicon oxynitride (SiON), hafnium oxide (HfO₂), hafnium silicon oxide (HfSiₓO_{y}), aluminum oxide (Al₂O₃), or zirconium oxide (ZrO₂).

The charge storage structure 154 may be an information storage structure in which charges are trapped and data is stored. As illustrated in FIG. 4, the charge storage structure 154 may have first to third regions R1, R2, and R3 sequentially arranged from the tunneling layer 156. The charge storage structure 154 may include charge trap layers 154T and barrier layers 154B1 and 154B2 between the charge trap layers 154T. The charge trap layers 154T may be layers in which charges are trapped, and the barrier layers 154B1 and 154B2 may be layers blocking or preventing movement of charges, for example, electrons. Trapping efficiency in the charge trap layers 154T may increase by the barrier layers 154B1 and 154B2. The barrier layers 154B1 and 154B2 may include first barrier layers 154B1 disposed in the first region R1, and second barrier layers 154B2 disposed in the second region R2.

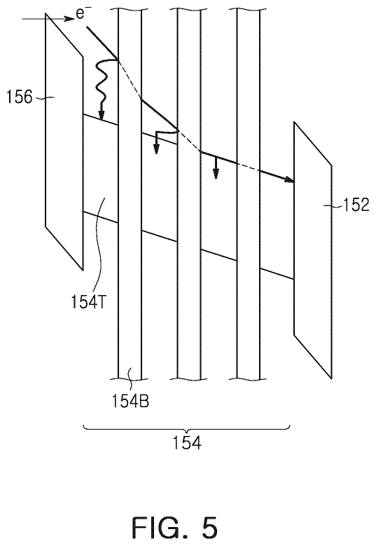

In the first to third regions R1, R2, and R3, densities of the barrier layers 154B1 and 154B2 may be different, and a region in which a density of a barrier layer is zero (e.g., the barrier layers 154B1 and 154B2 are absent) may be included. For example, the densities of the barrier layers 154B1 and 154B2 may mean ratios of areas occupied by the barrier layers 154B1 and 154B2 relative to a unit area of the charge storage structure 154, in the cross-section illustrated in FIG. 4. Alternatively, the densities of the barrier layers 154B1 and 154B2 may refer to ratios of volumes occupied by the barrier layers 154B1 and 154B2 relative to a unit volume of the charge storage structure 154. The barrier layers 154B1 and 154B2 may be arranged at a first density in the first region R1, may be arranged at a second density, lower than the first density, in the second region R2, and may be arranged at a third density, lower than the second density, in the third region R3. For example, the third region R3 may be a region in which the barrier layers 154B1 and 154B2 are not disposed. The first region R1 adjacent to the tunneling layer 156 may be a region including a dead zone having relatively low charge trapping efficiency. Accordingly, by arranging the first barrier layers 154B1 at a relatively high density in the first region R1, overall trapping efficiency of the charge storage structure 154 may increase. This will be explained in more detail with reference to FIG. 5 below.

In the first region R1, the first barrier layers 154B1 may have a first thickness T1 in a stacking direction, e.g., in a direction parallel to the upper surface of the plate layer 101. In the second region R2, the second barrier layers 154B2 may have a second thickness T2, smaller than the first thickness T1, in the stacking direction. The thickness of each of the barrier layers 154B1 and 154B2 may range from about 0.3 nm to about 1 nm, for example. In the first region R1, the first barrier layers 154B1 may be arranged at a first separation distance D1 in the stacking direction. In the second region R2, the second barrier layers 154B2 may have a second separation distance D2, greater than the first separation distance D1, in the stacking direction. The second separation distance D2 may be, for example, about 2 nm or less, for example, in the range of about 0.5 nm to about 2 nm.

A total thickness Tₜₒₜ of the charge storage structure 154 may range from about 4 nm to about 8 nm. The first region R1 may be thicker than the second region R2, and the number of first barrier layers 154B1 may be equal to or greater than the number of second barrier layers 154B2. For example, a thickness of the first region R1 may range from about 2.5 nm to about 3.5 nm. A thickness of the third region R3 may be smaller than a thickness of the first region R1 and a thickness of the second region R2. In some example embodiments, the thickness of the third region R3 may be greater than the second separation distance D2. In some example embodiments, the thickness of the third region R3 may be greater than a pitch of the first barrier layers 154B1 (e.g., a sum of the first thickness T1 and the first separation distance D1), and may be greater than a pitch of the second barrier layers 154B2. In the charge storage structure 154, relative thicknesses of the first to third regions R1, R2, and R3 may be changed. The number of first barrier layers 154B1 disposed in the first region R1, and the number of second barrier layers 154B2 disposed in the second region R2 may also vary in example embodiments, and, for example, may be 1 to 10.

The charge trap layers 154T may include an insulating material in which charges may be trapped. For example, the charge trap layers 154T may include silicon nitride, and may include, for example, silicon nitride having a Si₃N₄ composition, but the present inventive concepts are not limited thereto. The barrier layers 154B1 and 154B2 may include a two-dimensional insulating material, and may include, for example, boron nitride (BN), such as hexagonal boron nitride (h-BN) having a hexagonal crystal structure. The barrier layers 154B1 and 154B2 may include one to three layers of h-BN, respectively. Materials of the charge trap layers 154T are not limited to a two-dimensional insulating material, and may also include, in some example embodiments, BN having an amorphous structure, a cubic crystal structure, or a wurtzite crystal structure.

Charge trapping efficiency of the charge storage structure 154 may be improved by inserting the barrier layers 154B1 and 154B2, which may be two-dimensional insulating materials, at different densities for each of the regions, between the charge trap layers 154T in which charges are trapped, and, therefore, a program/erase window of the semiconductor device 100 may increase.

The buried channel insulating layer 160 may be disposed to fill the channel hole in the channel layer 140. The buried channel insulating layer 160 may include an insulating material, and may include, for example, silicon oxide (SiO₂), silicon nitride (Si₃N₄), silicon oxynitride (SiON), or a combination thereof.

The channel pad 165 may be disposed only in an upper portion of the upper channel structure CH2. The channel pad 165 may be arranged to fill an internal space defined by the channel layer 140 and the upper portion of the upper channel structure CH2. A lower surface of the channel pad 165 may be located on a higher level than an uppermost surface of the gate electrodes 130. The channel pad 165 may include, for example, doped polycrystalline silicon.

The channel dielectric layer 150, the channel layer 140, and the buried channel insulating layer 160 may be connected to each other between the first channel structure CH1 and the second channel structure CH2.

The first separation regions MS may be arranged to pass through the stack structure GS and extend in the X-direction. As illustrated in FIG. 1, the first separation regions MS may be arranged parallel to each other. As illustrated in FIG. 2, the first separation regions MS may pass through the stack structure GS, may further pass through the first and second horizontal conductive layers 102 and 104 at the lower portion thereof, and may be connected to the plate layer 101. The first separation regions MS may have a shape, the width of which decreases toward the plate layer 101 due to a high aspect ratio.

Upper surfaces of the first separation regions MS may be coplanar with upper surfaces of the channel structures CH. In some example embodiments, the upper surfaces of the first separation regions MS may be located on a higher level than the upper surfaces of the channel structures CH. The first separation regions MS may include an insulating material, and may include, for example, silicon oxide, silicon nitride, or silicon oxynitride.

The second separation region US may extend in the X-direction between a pair of the first separation regions MS that are adjacent to each other in the Y-direction. The second separation region US may pass through some of the gate electrodes 130 including the uppermost upper gate electrode 130U. As illustrated in FIG. 2, the second separation region US may, for example, separate a total of three gate electrodes 130 from each other in the Y-direction. The number of gate electrodes 130 separated by the second separation region US may be changed in various example embodiments. The second separation region US may include an insulating material, and may include, for example, silicon oxide, silicon nitride, or silicon oxynitride.

The cell region insulating layer 190 may be disposed on the stack structure GS. The cell region insulating layer 190 may cover the upper surfaces of the channel structures CH and the upper surfaces of the first separation regions MS. The cell region insulating layer 190 may be formed of an insulating material, and may include a plurality of insulating layers.

The studs 170 may be physically and electrically connected to the channel structures CH, respectively. The studs 170 may pass through the cell region insulating layer 190, and may be connected to the channel pads 165 of the channel structures CH, respectively. The studs 170 may electrically connect the channel structures CH and the bit lines 180. In some example embodiments, the studs 170 may be disposed to partially recess the channel pads 165. The studs 170 may include a conductive material, and may include, for example, tungsten (W), aluminum (Al), ruthenium (Ru), molybdenum (Mo), copper (Cu), or the like.

The bit lines 180 may be electrically connected to the channel structures CH through the studs 170. The bit lines 180 may be arranged to extend in the Y-direction, for example. The bit lines 180 may include a conductive material, such as metal, and may include, for example, tungsten (W), copper (Cu), aluminum (Al), or the like.

FIG. 5 is a view illustrating a semiconductor device according to an example embodiment.

Referring to FIG. 5, an energy band diagram for a tunneling layer 156, a charge storage structure 154, and a blocking layer 152 is illustrated, and a configuration in which electrons are trapped is schematically illustrated.

First, trapping efficiency in the charge storage structure 154 may be related to the capture rate of electrons, and a capture rate C (x) may be expressed by Equation 1 below. In Equation 1, w (x) is energy of an electron passing through the tunneling layer, Co is a maximum capture rate, and r is a constant.

$$C ( x ) = {C}_{0} exp ( - r w ( x ) ) \qquad [ Equation 1 ]$$

The w(x) may be expressed by the following equation 2. In Equation 2, E is an electric field of a charge trap layer, and λ is a decay length.

$$\frac{dw}{dx} = \frac{3}{5} qE - \frac{w ( x ) - w ( 0 )}{λ} \qquad [ Equation 2 ]$$

As illustrated in Equations 1 and 2 above, as energy of hot electrons passing through the tunneling layer increases, a capture rate may decrease. Therefore, as described above with reference to FIG. 4, a dead zone in which trapping efficiency is reduced may be formed in a region adjacent to the tunneling layer. However, in a charge storage structure 154 according to the disclosed example embodiments, trapping efficiency may be improved as described below.

As illustrated in FIG. 5, the charge storage structure 154 may include barrier layers 154B interposed in a charge trap layer 154T. Bandgap energy of the barrier layers 154B may be greater than bandgap energy of the charge trap layer 154T. For example, the bandgap energy of the barrier layers 154B may be greater than bandgap energy of the tunneling layer 156 and bandgap energy of the blocking layer 152. Therefore, as indicated by an arrow in FIG. 5, a portion of electrons injected from the tunneling layer 156 may be reflected due to an energy barrier of the barrier layers 154B to reduce energy w (x), and may be thus captured even in a region adjacent to the tunneling layer 156. Even though a portion of the electrons pass through the barrier layers 154B, because effective mass thereof in the barrier layers 154B may be large, the portion of the electrons may lose energy quickly and thus may be captured more quickly. Therefore, trapping efficiency in the region adjacent to the tunneling layer 156 may increase.

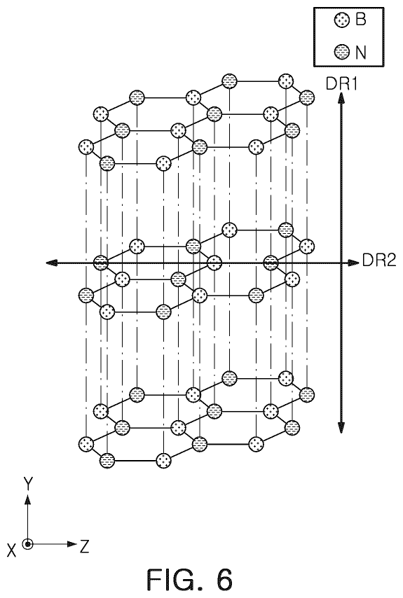

FIG. 6 is a view illustrating a semiconductor device according to an example embodiment.

Referring to FIG. 6, a crystal structure of h-BN that may be used as barrier layers 154B1 and 154B2 of a charge storage structure 154 is illustrated. In the h-BN, B:N may have a ratio of 1:1. Because the h-BN is a two-dimensional material, a thickness of a first layer may be as thin as approximately 0.3 nm, thereby minimizing an increase in thickness of the charge storage structure 154 in total. Bandgap energy of the h-BN in an in-plane direction DR2 may be about 5.65 eV, slightly larger than that of silicon nitride, but bandgap energy of the h-BN in an out-of-plane direction DR1 may be large enough to be undefined, and movement of electrons in the out-of-plane direction DR1 may be limited. For example, the bandgap energy in the out-of-plane direction DR1 may be greater than 10 eV. The out-of-plane direction DR1 may correspond to a thickness direction or a stacking direction in a channel structure CH. Therefore, when the barrier layers 154B1 and 154B2 include the h-BN, the increase in thickness of the charge storage structure 154 may be minimized, trap sites of charge trap layers 154T may be maintained in the same manner, and trapping efficiency may increase.

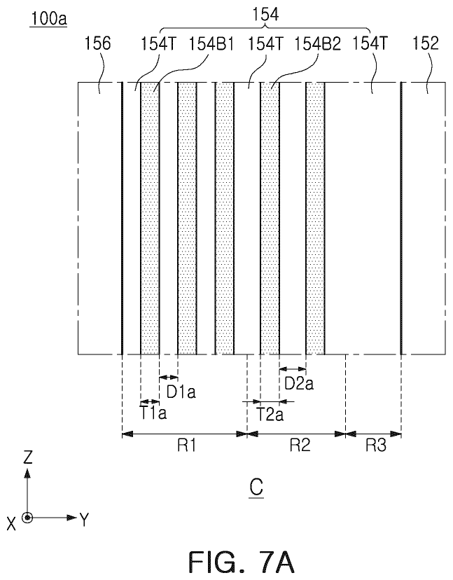

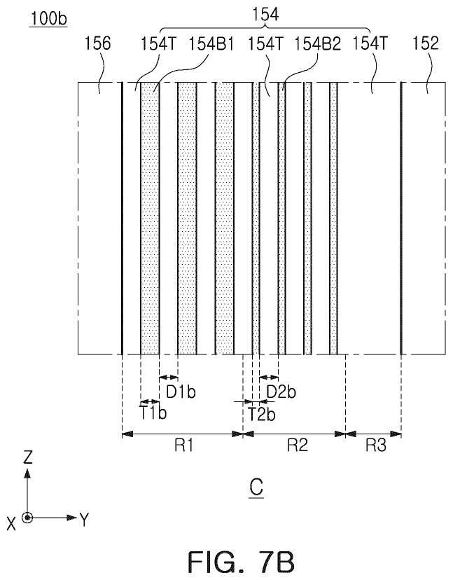

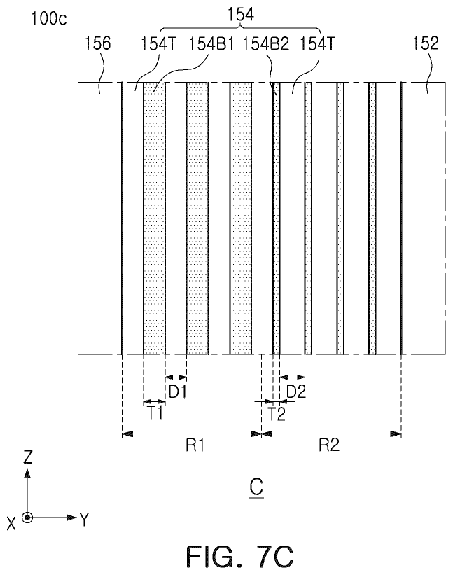

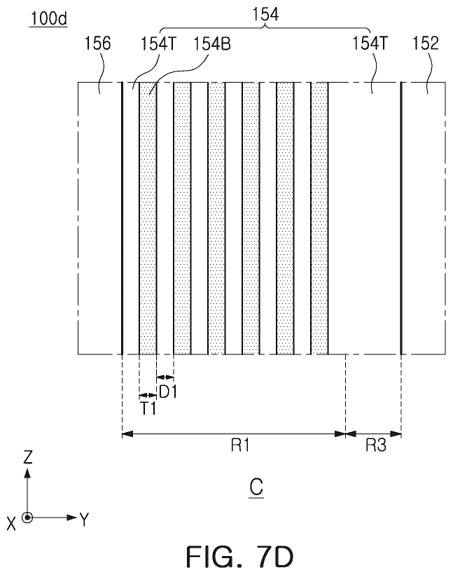

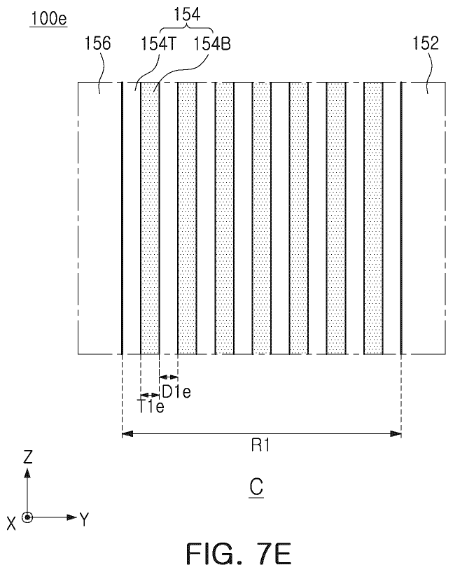

FIGS. 7A to 7E are schematic partially enlarged views of semiconductor devices according to some example embodiments. FIGS. 7A to 7E illustrate regions corresponding to FIG. 4, respectively.

Referring to FIG. 7A, in a charge storage structure 154 of a semiconductor device 100a, a first thickness T1a of first barrier layers 154B1 may be substantially the same as a second thickness T2a of second barrier layers 154B2. The thickness of each of the barrier layers 154B1 and 154B2 may range from about 0.3 nm to about 1 nm, for example. In a first region R1, the first barrier layers 154B1 may be arranged at a first separation distance D1a in a stacking direction. In a second region R2, the second barrier layers 154B2 may have a second separation distance D2a, greater than the first separation distance D1a, in the stacking direction.

Referring to FIG. 7B, in a charge storage structure 154 of a semiconductor device 100b, a separation distance D1b between first barrier layers 154B1 in a first region R1 may be substantially equal to a second separation distance D2b between second barrier layers 154B2 in a second region R2. A first thickness T1b of the first barrier layers 154B1 may be greater than a second thickness T2b of the second barrier layers 154B2.

Referring to FIG. 7C, a charge storage structure 154 of a semiconductor device 100c may not include a third region R3, unlike the example embodiment of FIG. 4. The description of FIG. 4 may be equally applied to first and second regions R1 and R2. Similarly, a third region R3 may be omitted in the example embodiments of FIGS. 7A and 7B.

Referring to FIG. 7D, a charge storage structure 154 of a semiconductor device 100d may not include a second region R2, unlike the example embodiment of FIG. 4. The charge storage structure 154 may include a first region R1 in which barrier layers 154B are disposed, and a third region R3 in which the barrier layers 154B are not disposed. Sizes and relative sizes of a thickness T1 and a separation distance D1 of the barrier layers 154B may be changed, respectively, in various example embodiments. In some example embodiments, relative thicknesses of the first region R1 and the third region R3 may be changed. The description of FIG. 4 may be equally applied to the first and third regions R1 and R3.

Referring to FIG. 7E, a charge storage structure 154 of a semiconductor device 100e may include only a first region R1, unlike the example embodiment of FIG. 4. Barrier layers 154B may be uniformly disposed throughout the charge storage structure 154. Sizes and relative sizes of a thickness T1e and a separation distance D1e of the barrier layers 154B may be changed, respectively, in various example embodiments.

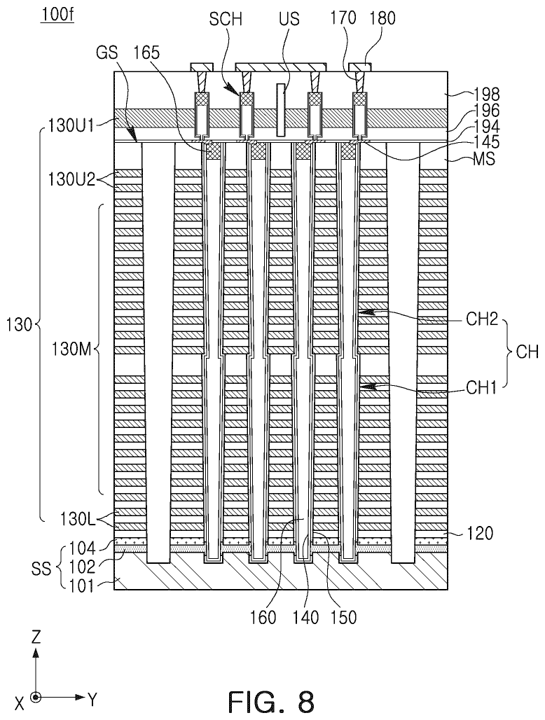

FIG. 8 is a cross-sectional view illustrating a semiconductor device according to an example embodiment.

Referring to FIG. 8, a semiconductor device 100f may further include string channel structures SCH connected to channel structures CH, and a horizontal insulating layer 194. First and second cell region insulating layers 196 and 198 may be included.

A first upper gate electrode 130U1, which is located in an uppermost portion, among gate electrodes 130, may be disposed to be relatively thick. The string channel structures SCH may be disposed to pass through the first upper gate electrode 130U1, and the channel structures CH may be disposed to pass through the gate electrodes 130 excluding the first upper gate electrode 130U1.

The string channel structures SCH may be connected to channel structures CH, respectively. The string channel structures SCH may be arranged below the channel structures CH, respectively, or may be arranged shifted from the channel structures CH in a horizontal direction, but the present inventive concepts are not limited thereto. Each of the string channel structures SCH may include a string channel layer disposed in a string channel hole, and may have the same or similar structure as the channel structures CH. The string channel layer SCH may be connected to a connection pad 145 on a lower end, and may be electrically connected to a channel layer 140 of a channel structure CH through the connection pad 145. The connection pad 145 may include a conductive material, and may include, for example, polycrystalline silicon.

The horizontal insulating layer 194 may be disposed between the channel structures CH and the string channel structures SCH, and may extend horizontally. The horizontal insulating layer 194 may be disposed between the first upper gate electrode 130U1 and second upper gate electrodes 130U2. The horizontal insulating layer 194 may be used as an etch stop layer when forming the string channel structures SCH, and may also be a layer used when forming the connection pads 145. The horizontal insulating layer 194 may include an insulating material, and may include a different material from interlayer insulating layers 120 and the first cell region insulating layer 196.

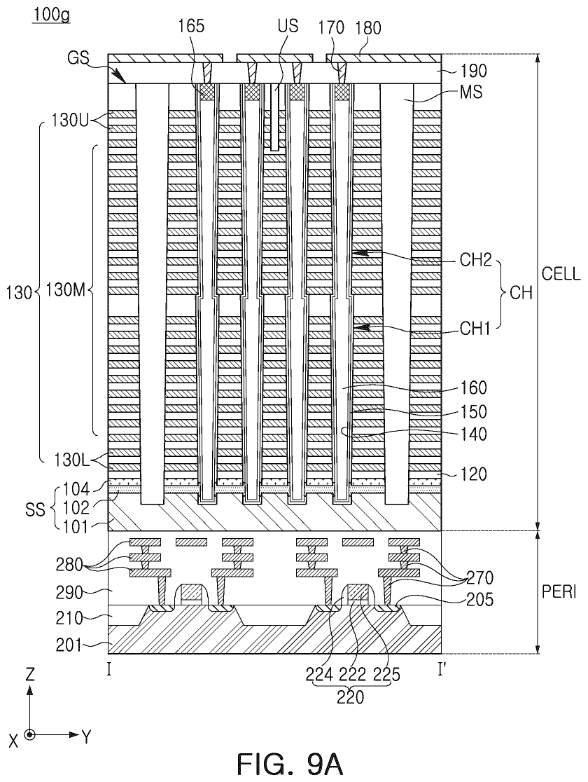

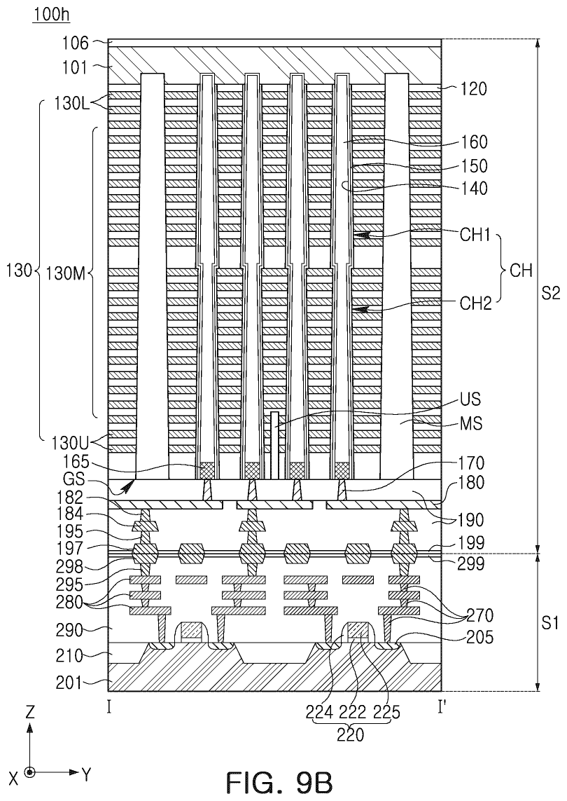

FIGS. 9A and 9B are schematic cross-sectional views of semiconductor devices according to some example embodiments.

Referring to FIG. 9A, a semiconductor device 100g may include a memory cell region CELL and a peripheral circuit region PERI, stacked vertically. The memory cell region CELL may be disposed on the peripheral circuit region PERI. For example, in the semiconductor device 100 of FIG. 2, the peripheral circuit region PERI may be disposed on the plate layer 101 in a region not illustrated, or as in the semiconductor device 100g of the present embodiment, the peripheral circuit region PERI may be disposed below the plate layer 101. In some example embodiments, the memory cell region CELL may be disposed below the peripheral circuit region PERI. Descriptions of the memory cell region CELL referring to FIGS. 1 to 4 may be identically applied to this example embodiment.

The peripheral circuit region PERI may include a substrate 201, impurity regions 205 and device isolation layers 210 in the substrate 201, and circuit elements 220, a peripheral region insulating layer 290, circuit contact plugs 270, and circuit interconnection lines 280, arranged on the substrate 201.

The substrate 201 may have an upper surface extending in the X-direction and Y-direction. An active region may be defined on the substrate 201 by the device isolation layers 210. The impurity regions 205 containing impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit elements 220 may include a planar transistor. Each of the circuit elements 220 may include a circuit gate dielectric layer 222, a spacer layer 224, and a circuit gate electrode 225. The impurity regions 205 may be disposed as source/drain regions in the substrate 201 on both sides of the circuit gate electrode 225.

The peripheral region insulating layer 290 may be disposed on the circuit element 220 on the substrate 201. The peripheral region insulating layer 290 may include a plurality of insulating layers formed in different process operations. The peripheral region insulating layer 290 may be formed of an insulating material.

The circuit contact plugs 270 and the circuit interconnection lines 280 may form a circuit interconnection structure electrically connected to the circuit elements 220 and the impurity regions 205. The circuit contact plugs 270 may have a cylindrical shape, and the circuit interconnection lines 280 may have a line shape. An electrical signal may be applied to the circuit element 220 through the circuit contact plugs 270 and the circuit interconnection lines 280. In a region not illustrated, the circuit contact plugs 270 may also be connected to the circuit gate electrode 225. The circuit interconnection lines 280 may be connected to the circuit contact plugs 270, and may be arranged as multiple layers. The circuit contact plugs 270 and the circuit interconnection lines 280 may include a conductive material, and may include, for example, tungsten (W), copper (Cu), aluminum (Al), or the like, and configurations thereof may further include a diffusion barrier. In example embodiments, the number of layers of circuit contact plugs 270 and circuit interconnection lines 280 may be changed.

In this manner, a configuration in which the memory cell region CELL and the peripheral circuit region PERI are vertically stacked may be applied to other example embodiments.

Referring to FIG. 9B, a semiconductor device 100h may include a first semiconductor structure S1 and a second semiconductor structure S2 bonded using a wafer bonding process.

Description of the peripheral circuit region PERI described above with reference to FIG. 9A may be applied to the first semiconductor structure S1. The first semiconductor structure S1 may further include first bonding vias 295, first bonding metal layers 298, and first bonding insulating layer 299, which may be bonding structures. The first bonding vias 295 may be disposed on uppermost circuit interconnection lines 280, and may be connected to circuit interconnection lines 280. At least a portion of the first bonding metal layers 298 may be connected to the first bonding vias 295 on the first bonding vias 295. The first bonding metal layers 298 may be connected to second bonding metal layers 197 of the second semiconductor structure S2. The first bonding metal layers 298 and the second bonding metal layers 197 may provide an electrical connection path for bonding the first semiconductor structure S1 and the second semiconductor structure S2. A portion of the first bonding metal layers 298 may not be connected to lower circuit interconnection lines 280, and may be disposed only for bonding. The first bonding vias 295 and the first bonding metal layers 298 may include a conductive material, for example, copper (Cu). The first bonding insulating layer 299 may be disposed around the first bonding metal layers 298. The first bonding insulating layer 299 may also function as a diffusion prevention layer of the first bonding metal layers 298, and may include, for example, at least one of SiN, SiON, SiCN, SiOC, SiOCN, or SiO.

For the second semiconductor structure S2, unless otherwise specified, description of the memory cell region CELL described above with reference to FIGS. 1 to 4 may be applied. The second semiconductor structure S2 may further include lower contact plugs 182 and cell interconnection lines 184, which may be cell interconnection structures, and may further include a bonding structure, which include second bonding vias 195, second bonding metal layers 197, and a second bonding insulating layer 199. The second semiconductor structure S2 may further include a passivation layer 106 covering an upper surface of a plate layer 101.

The lower contact plugs 182 may be connected to bit lines 180, and the cell interconnection lines 184 may be connected to the lower contact plugs 182. In example embodiments, the number of layers and arrangement of contact plugs and interconnection lines forming the cell interconnection structure may be changed. The lower contact plugs 182 and the cell interconnection lines 184 may be formed of a conductive material, and may include, for example, at least one of tungsten (W), aluminum (Al), or copper (Cu).

The second bonding vias 195 and the second bonding metal layers 197 may be disposed below lowermost cell interconnection lines 184. The second bonding vias 195 may connect the cell interconnection lines 184 and the second bonding metal layers 197, and the second bonding metal layers 197 may be joined with the first bonding metal layers 298 of the first semiconductor structure S1. The second bonding insulating layer 199 may be connected to the first bonding insulating layer 299 of the first semiconductor structure S1 by bonding. The second bonding vias 195 and the second bonding metal layers 197 may include a conductive material, for example, copper (Cu). The second bonding insulating layer 199 may include, for example, at least one of SiO, SiN, SiCN, SiOC, SiON, or SiOCN.

The first and second semiconductor structures S1 and S2 may be bonded by joining the first bonding metal layers 298 and the second bonding metal layers 197 and joining the first bonding insulating layer 299 and the second bonding insulating layer 199. The joining of the first bonding metal layers 298 and the second bonding metal layers 197 may be, for example, copper (Cu)-to-copper (Cu) bonding, and the joining of the first bonding insulating layer 299 and the second bonding insulating layer 199 may be, for example, dielectric-to-dielectric bonding, such as SiCN-to-SiCN bonding. The first and second semiconductor structures S1 and S2 may be joined by hybrid bonding including the copper (Cu)-to-copper (Cu) bonding and the dielectric-to-dielectric bonding.

The passivation layer 106 may be disposed on the upper surface of the plate layer 101, and may protect the semiconductor device 100h. The passivation layer 106 may include an insulating material, for example, at least one of silicon oxide, silicon nitride, or silicon carbide, and may be formed as a plurality of insulating layers, depending on example embodiments.

In the present example embodiment, the second semiconductor structure S2 may not include first and second horizontal conductive layers 102 and 104 (see FIG. 2). Channel structures CH may be directly connected to the plate layer 101 with channel layers 140 exposed through an upper end thereof. An electrical connection form of the channel structures CH and a common source line may be changed in various example embodiments, and the channel structures CH and a source structure SS may have the same structure as the example embodiment of FIG. 2.

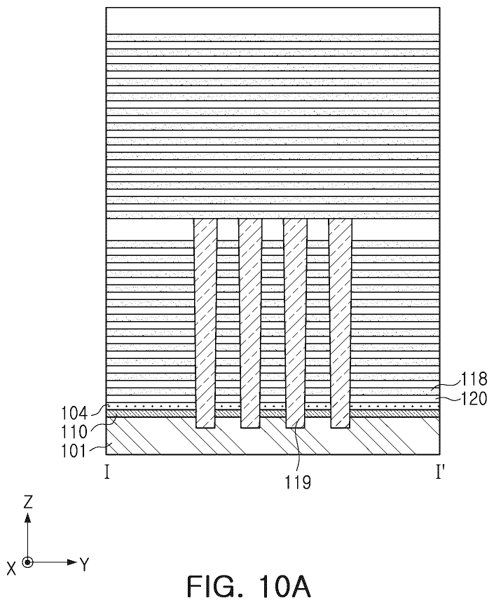

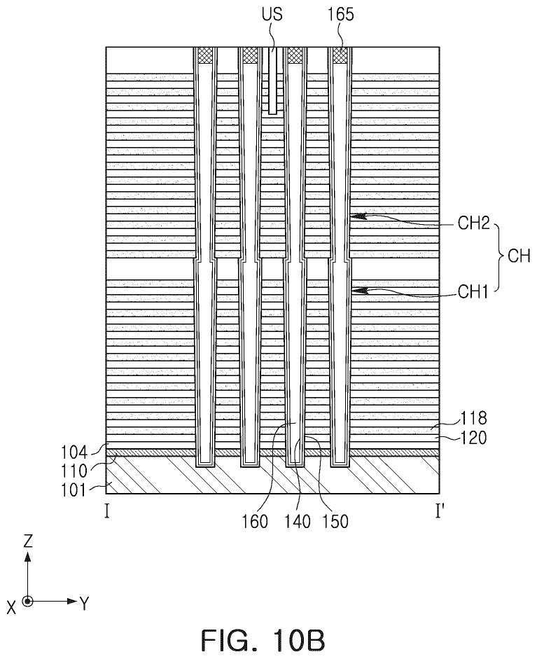

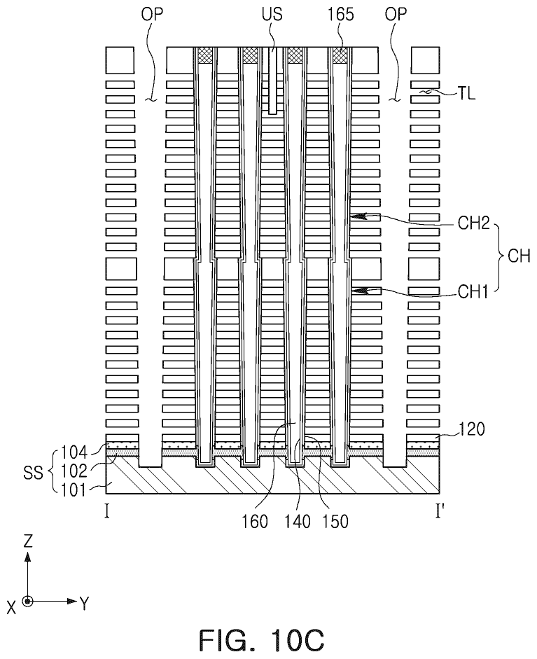

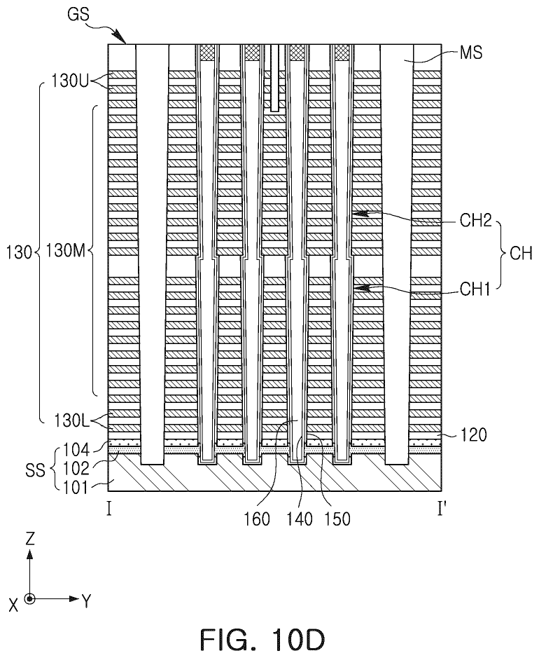

FIGS. 10A to 10D are schematic cross-sectional views illustrating a method of manufacturing a semiconductor device according to an example embodiment. FIGS. 10A to 10D illustrate regions corresponding to FIG. 2, respectively.

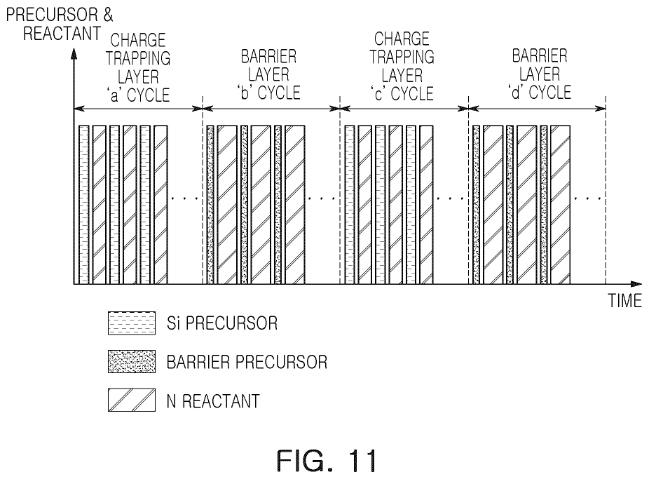

FIG. 11 is a view illustrating a method of manufacturing a semiconductor device according to an example embodiment.

Referring to FIG. 10A, a lower mold structure may be formed by alternately stacking sacrificial insulating layers 118 and interlayer insulating layers 120, vertical sacrificial layers 119 passing through the lower mold structure may be formed, and an upper mold structure may be formed.

A horizontal sacrificial layer 110 may include a plurality of layers containing different materials. The horizontal sacrificial layer 110 may be a layer that may be replaced with a first horizontal conductive layer 102 (see FIG. 2) by a subsequent process. For example, the horizontal sacrificial layer 110 may include a first layer and a third layer, formed of the same material as the interlayer insulating layers 120, and may further include a second layer formed of the same material as the sacrificial insulating layers 118 and disposed between the first layer and the third layer. A second horizontal conductive layer 104 may be formed on the horizontal sacrificial layer 110.

The sacrificial insulating layers 118 may be a layer that may be replaced with gate electrodes 130 (see FIG. 2) by a subsequent process. The sacrificial insulating layers 118 may be formed of a different material from the interlayer insulating layers 120, and may be formed of a material that may be etched with etch selectivity under specific etching conditions with respect to the interlayer insulating layers 120. For example, the interlayer insulating layer 120 may be formed of at least one of silicon oxide or silicon nitride, and the sacrificial insulating layers 118 may be formed of a material selected from silicon, silicon oxide, silicon carbide, or silicon nitride, and different from the interlayer insulating layer 120.

The vertical sacrificial layers 119 may be formed in regions corresponding to the first channel structures CH1 of FIG. 2. The vertical sacrificial layers 119 may be prepared by forming lower channel holes to pass through the lower mold structure, depositing a material forming the vertical sacrificial layers 119 in the lower channel holes, and performing a planarization process. The vertical sacrificial layers 119 may include a material different from the interlayer insulating layers 120 and the sacrificial insulating layers 118. For example, the vertical sacrificial layers 119 may include a semiconductor material such as polycrystalline silicon, a silicon-based insulating material, or a carbon-based material.

The upper mold structure may be formed on the lower mold structure on a height level on which second channel structures CH2 (see FIG. 2) of channel structures CH are disposed. The upper mold structure may be formed by alternately stacking the sacrificial insulating layers 118 and the interlayer insulating layers 120 in the same manner as the lower mold structure.

Referring to FIG. 10B, channel structures CH passing through the lower mold structure and the upper mold structure may be formed.

First, upper vertical sacrificial layers passing through the upper mold structure may be formed. The upper vertical sacrificial layers may be formed at positions corresponding to upper channel structures CH2. The upper vertical sacrificial layers may be formed to be connected to the vertical sacrificial layers 119, respectively.

The channel structures CH may be prepared by removing the vertical sacrificial layers 119 and the upper vertical sacrificial layers to form hole-shaped channel holes, sequentially depositing a channel dielectric layer 150, a channel layer 140, and a buried channel insulating layer 160 in the channel holes, and forming a channel pad 165.

The channel dielectric layer 150 may be formed to have a uniform thickness using an atomic layer deposition (ALD) process or a chemical vapor deposition (CVD) process. In the channel dielectric layer 150, a charge storage structure 154 may be formed by alternately depositing charge trap layers 154T and barrier layers 154B1 and 154B2, as described above with reference to FIG. 4.

Referring to FIG. 11, injection flow of precursors and reactants in forming the charge storage structure 154 using the ALD process is illustrated. First, to form the charge trap layer 154T, a silicon nitride layer may be formed by alternately injecting a silicon (Si) precursor and a nitrogen (N) reactant. Next, to form the barrier layers 154B1 and 154B2, a boron nitride layer may be formed by alternately injecting a barrier precursor, such as a boron (B) precursor, and a nitrogen (N) reactant. A process temperature may be set to have a temperature at which both silicon nitride and boron nitride are formed. The charge storage structure 154 may be formed by alternately performing cycles a and c for forming the charge trap layer 154T, and cycles b and d for forming the barrier layers 154B1 and 154B2.

The channel layer 140 may be formed on the channel dielectric layer 150 within the channel holes. The buried channel insulating layer 160 may be formed to fill the channel holes, and may be formed of an insulating material. The channel pad 165 may be formed after partially removing the buried channel insulating layer 160. The channel pad 165 may be formed of a conductive material, and may be formed of, for example, polycrystalline silicon.

Referring to FIG. 10C, a first horizontal conductive layer 102 may be formed and the sacrificial insulating layers 118 may be removed.

Openings may be formed in positions of first separation regions MS (see FIG. 1). The openings may be formed to pass through the sacrificial insulating layers 118 and the interlayer insulating layers 120 and to extend toward the plate layer 101. The horizontal sacrificial layer 110 may be selectively removed through the openings, and a portion of the exposed channel dielectric layer 150 may also be removed. The first horizontal conductive layer 102 may be formed by depositing a conductive material in a region from which the horizontal sacrificial layer 110 has been removed.

The sacrificial insulating layers 118 may be removed selectively with respect to the interlayer insulating layers 120, the second horizontal conductive layer 104, and the channel structures CH, using wet etching, for example. Tunnel portions TL may be formed in a region from which the sacrificial insulating layers 118 have been removed.

Referring to FIG. 10D, gate electrodes 130 may be formed.

The gate electrodes 130 may be formed by depositing a conductive material on the tunnel portions TL. In some example embodiments, a portion of the channel dielectric layer 150 may be formed first before forming the gate electrodes 130. After forming the gate electrodes 130, first separation regions MS may be formed by depositing an insulating material in the openings.

Next, referring to FIG. 2 together, a cell region insulating layer 190 may be formed, and studs 170 and bit lines 180 may be formed.

The cell region insulating layer 190 may be formed to cover upper surfaces of the stack structure GS and the channel structures CH. The studs 170 may be formed to pass through the cell region insulating layer 190 and be connected to the channel structures CH. The bit lines 180 may be formed to be connected to the studs 170. Thus, the semiconductor device 100 of FIG. 2 may be manufactured.

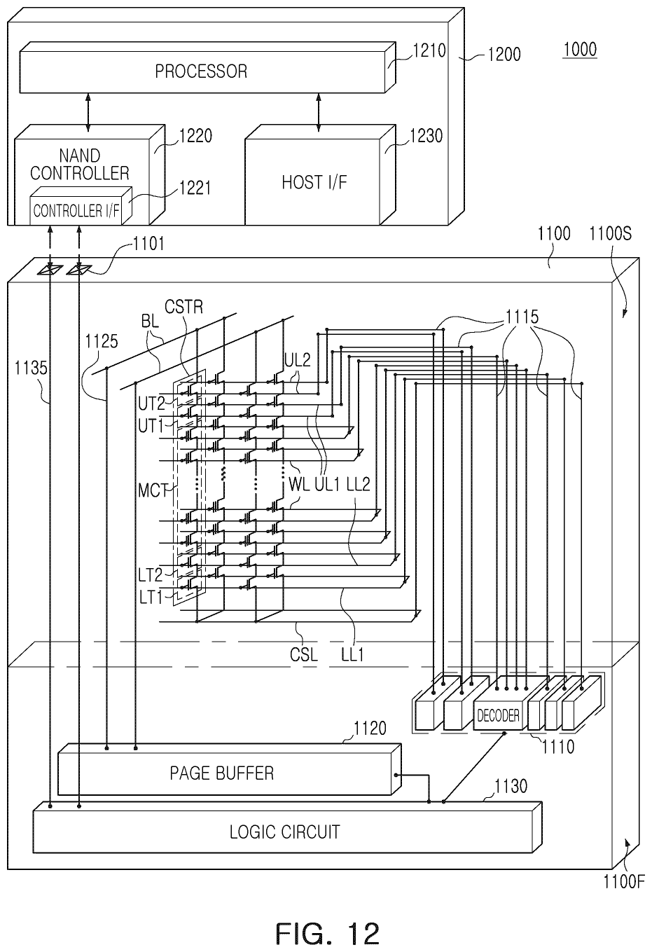

FIG. 12 is a view schematically illustrating a data storage system including a semiconductor device according to an example embodiment.

Referring to FIG. 12, a data storage system 1000 may include a semiconductor device 1100, and a controller 1200 electrically connected to the semiconductor device 1100. The data storage system 1000 may be a storage device including the semiconductor device 1100 as a single semiconductor device or a plurality of semiconductor devices, or an electronic device including the storage device. For example, the data storage system 1000 may be a solid state drive device (SSD), a universal serial bus (USB), a computing system, a medical device, or a communication device, including the semiconductor device 1100 as a single semiconductor device or a plurality of semiconductor devices.

The semiconductor device 1100 may be a non-volatile memory device, and may be, and may include, for example, a NAND flash memory device, as described above with reference to FIGS. 1 to 9B. The semiconductor device 1100 may include a first structure 1100F, and a second structure 1100S on the first structure 1100F. In some example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CUS_SL, word lines WL, first and second upper gate lines UL1 and UL2, first and second lower gate lines LL1 and LL2, and memory cell strings CSTR between the bit line BL and the common source line CUS_SL.

In the second structure 1100S, each of the memory cell strings CSTR may include lower transistors LT1 and LT2 adjacent to the common source line CUS_SL, upper transistors UT1 and UT2 adjacent to the bit line BL, and a plurality of memory cell transistors MCT disposed between each of the lower transistors LT1 and LT2 and each of the upper transistors UT1 and UT2. The number of lower transistors LT1 and LT2 and the number of upper transistors UT1 and UT2 may be variously changed according to example embodiments.

In some example embodiments, each of the upper transistors UT1 and UT2 may include a string select transistor, and each of the lower transistors LT1 and LT2 may include a ground select transistor. The lower gate lines LL1 and LL2 may be gate electrodes of the lower transistors LT1 and LT2, respectively. The word lines WL may be gate electrodes of the memory cell transistors MCT, and the upper gate lines UL1 and UL2 may be gate electrodes of the upper transistors UT1 and UT2, respectively.

In some example embodiments, the lower transistors LT1 and LT2 may include a lower erase control transistor LT1 and a ground select transistor LT2, connected in series. The upper transistors UT1 and UT2 may include a string select transistor UT1 and an upper erase control transistor UT2, connected in series. At least one of the lower erase control transistor LT1 or the upper erase control transistor UT2 may be used for an erase operation of erasing data stored in the memory cell transistors MCT using a gate-induced-drain-leakage (GIDL) phenomenon.

The common source line CUS_SL, the first and second lower gate lines LL1 and LL2, the word lines WL, and the first and second upper gate lines UL1 and UL2 may be electrically connected to the decoder circuit 1110 through first connection wirings 1115 extending from the first structure 1100F into the second structure 1100S. The bit lines BL may be electrically connected to the page buffer 1120 through second connection wirings 1125 extending from the first structure 1100F into the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wiring 1135 extending from the first structure 1100F into the second structure 1100S.

The controller 1200 may include a processor 1210, a NAND controller 1220, and a host interface 1230. According to embodiments, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a desired (or alternatively, predetermined) firmware, and may access to the semiconductor device 1100 by controlling the NAND controller 1220. The NAND controller 1220 may include a controller interface 1221 processing communications with the semiconductor device 1100. A control command for controlling the semiconductor device 1100, data to be written to the memory cell transistors MCT of the semiconductor device 1100, data to be read from the memory cell transistors MCT of the semiconductor device 1100, or the like may be transmitted through the controller interface 1221. The host interface 1230 may provide a communication function between the data storage system 1000 and an external host. When a control command is received from the external host through the host interface 1230, the processor 1210 may control the semiconductor device 1100 in response to the control command.

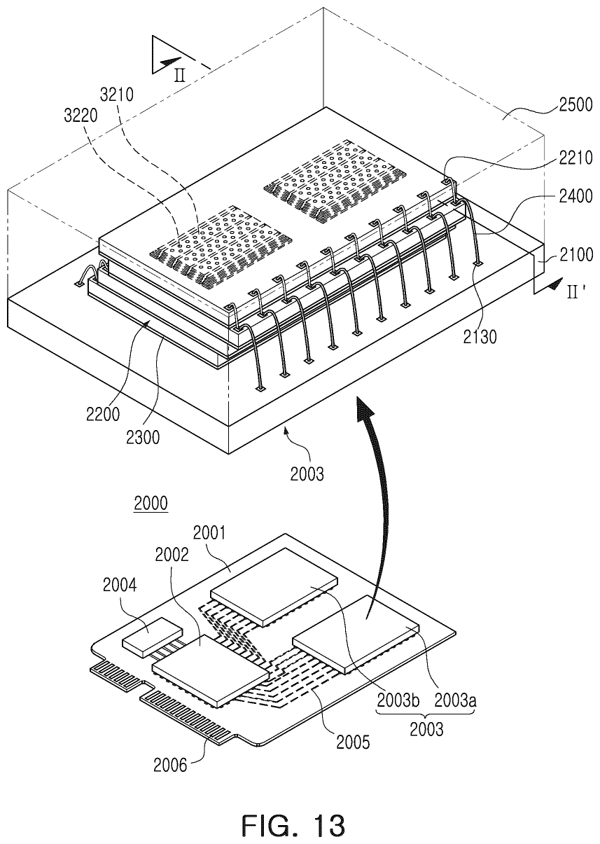

FIG. 13 is a perspective view schematically illustrating a data storage system including a semiconductor device according to an example embodiment.

Referring to FIG. 13, a data storage system 2000 according to an example embodiment may include a main substrate 2001, a controller 2002 mounted on the main substrate 2001, at least one semiconductor package 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins, which may be coupled to an external host. The number and arrangement of the plurality of pins in the connector 2006 may be changed according to a communication interface between the data storage system 2000 and the external host. In some example embodiments, the data storage system 2000 may be communicated with the external host according to any one interface of a universal serial bus (USB), peripheral component interconnect express (PCI-Express), serial advanced technology attachment (SATA), M-Phy for universal flash storage (UFS), or the like. In example embodiments, the data storage system 2000 may be operated by power supplied from the external host through the connector 2006. The data storage system 2000 may further include a power management integrated circuit (PMIC) distributing power, supplied from the external host, to the controller 2002 and the semiconductor package 2003.

The controller 2002 may write data to the semiconductor package 2003 or read data from the semiconductor package 2003, and may improve an operation speed of the data storage system 2000.

The DRAM 2004 may be a buffer memory reducing a difference in speed between the semiconductor package 2003, which may be a data storage space, and the external host. The DRAM 2004 included in the data storage system 2000 may also operate as a type of cache memory, and may provide a space temporarily storing data in a control operation on the semiconductor package 2003. When the DRAM 2004 is included in the data storage system 2000, the controller 2002 may further include a DRAM controller controlling the DRAM 2004 in addition to a NAND controller controlling the semiconductor package 2003.

The semiconductor package 2003 may include first and second semiconductor packages 2003a and 2003b, spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting each of the semiconductor chips 2200 and the package substrate 2100, and a molding layer 2500 covering the semiconductor chips 2200 and the connection structure 2400 on the package substrate 2100.

The package substrate 2100 may be a printed circuit board including upper package pads 2130. Each of the semiconductor chips 2200 may include an input/output pad 2210. The input/output pad 2210 may correspond to the input/output pad 1101 of FIG. 12. Each of the semiconductor chips 2200 may include gate stack structures 3210 and channel structures 3220. Each of the semiconductor chips 2200 may include the semiconductor device described above with reference to FIGS. 1 to 9B.

In some example embodiments, the connection structure 2400 may be a bonding wire electrically connecting the input/output pad 2210 and the upper package pads 2130. Therefore, in each of the first and second semiconductor packages 2003a and 2003b, the semiconductor chips 2200 may be electrically connected to each other by a bonding wire process, and may be electrically connected to the package upper pads 2130 of the package substrate 2100. According to some example embodiments, in each of the first and second semiconductor packages 2003a and 2003b, the semiconductor chips 2200 may be electrically connected to each other by a connection structure including a through silicon via (TSV), instead of the connection structure 2400 by the bonding wire process.

In some example embodiments, the controller 2002 and the semiconductor chips 2200 may be included in one (1) package. In an example embodiment, the controller 2002 and the semiconductor chips 2200 may be mounted on a separate interposer substrate, different from the main substrate 2001, and the controller 2002 and the semiconductor chips 2200 may be connected to each other by a wiring formed on the interposer substrate.

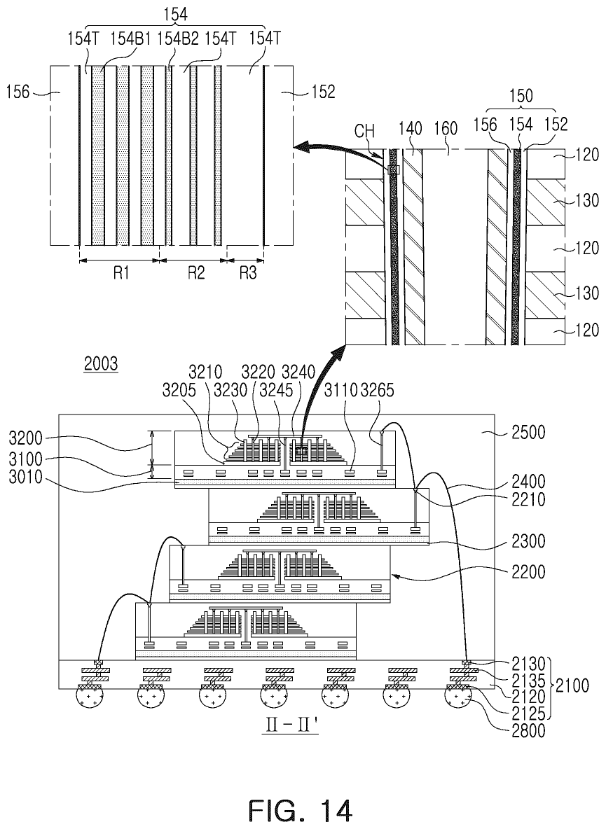

FIG. 14 is a cross-sectional view schematically illustrating a semiconductor package according to an example embodiment. FIG. 14 illustrates an example of the semiconductor package 2003 of FIG. 13, and conceptually illustrates a region taken along line II-II′ of the semiconductor package 2003 of FIG. 13.

Referring to FIG. 14, in the semiconductor package 2003, the package substrate 2100 may be a printed circuit board. The package substrate 2100 may include a package substrate body portion 2120, upper package pads 2130 disposed on an upper surface of the package substrate body portion 2120, lower pads 2125 disposed on a lower surface of the package substrate body portion 2120 or exposed from the lower surface, and internal wirings 2135 electrically connecting the upper package pads 2130 and the lower pads 2125 in the package substrate body portion 2120. The lower pads 2125 may be connected to the wiring patterns 2005 of the main substrate 2001 of the data storage system 2000, as illustrated in FIG. 12, through conductive connection portions 2800.

Each of the semiconductor chips 2200 may include a semiconductor substrate 3010, and a first structure 3100 and a second structure 3200, sequentially stacked on the semiconductor substrate 3010. The first structure 3100 may include a peripheral circuit region including peripheral wirings 3110. The second structure 3200 may include a common source line 3205, a gate stack structure 3210 on the common source line 3205, channel structures 3220 and separation regions 3230, passing through the gate stack structure 3210, and bit lines 3240 electrically connected to the channel structures 3220. As described above with reference to FIGS. 1 to 9B, in each of the semiconductor chips 2200, a charge storage structure 154 in channel structures CH may include charge trap layers 154T and barrier layers 154B1 and 154B2. The barrier layers 154B1 and 154B2 may be arranged at a relatively high density in a first region R1 adjacent to a tunneling layer 156.

Each of the semiconductor chips 2200 may include a through-interconnection 3245 electrically connected to the peripheral wirings 3110 of the first structure 3100 and extending into the second structure 3200. The through-interconnection 3245 may be disposed outside the gate stack structure 3210, and may further be disposed to pass through the gate stack structure 3210. Each of the semiconductor chips 2200 may further include an input/output connection wiring 3265 electrically connected to the peripheral wirings 3110 of the first structure 3100 and extending into the second structure 3200, and an input/output pad 2210 electrically connected to the input/output connection wiring 3265.

A charge storage structure including charge trap layers of silicon nitride and barrier layers of a 2D insulating material interposed therebetween may be included to provide a semiconductor device having improved electrical characteristics and reliability and a data storage system including the same.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Various advantages and effects of the present inventive concepts are not limited to the above-described content, and can be more easily understood through description of specific example embodiments of the present inventive concepts.

While some example embodiments have been illustrated and described above, it will be apparent to those skilled in the art that modifications, variations, and combinations of the disclosed example embodiments could be made without departing from the scope of the present inventive concepts as defined by the appended claims.

What is claimed is:

1. A semiconductor device comprising:
a plate layer;
gate electrodes stacked on the plate layer, the gate electrodes spaced apart from each other in a first direction, the first direction being perpendicular to an upper surface of the plate layer, the gate electrodes including channel holes passing therethrough and extending in the first direction; and
channel structures in the channel holes, each of the channel structures including a blocking layer, a charge storage structure, a tunneling layer, a channel layer, and a buried channel insulating layer that are sequentially arranged from the gate electrodes in a second direction, the second direction being perpendicular to the first direction,
wherein the charge storage structure has a first region adjacent to the tunneling layer, a second region between the first region and the blocking layer, and a third region between the second region and the blocking layer,
wherein the charge storage structure includes charge trap layers and barrier layers between the charge trap layers, and
wherein the barrier layers each have a first thickness in the first region and a second thickness in the second region, the second thickness being less than the first thickness, and the barrier layers are absent in the third region.

2. The semiconductor device of claim 1, wherein the barrier layers are arranged at a first separation distance in the first region and arranged at a second separation distance in the second region, the second separation distance being greater than the first separation distance.

3. The semiconductor device of claim 2, wherein the third region has a thickness, greater than the second separation distance.

4. The semiconductor device of claim 1, wherein a thickness of the third region is greater than a pitch of the barrier layers in the first region and a pitch of the barrier layers in the second region.

5. The semiconductor device of claim 1, wherein the barrier layers comprise a material having a first bandgap energy along the first direction and a second bandgap energy along the second direction, the second bandgap energy being greater than the first bandgap energy.

6. The semiconductor device of claim 1, wherein
the charge trap layers comprise silicon nitride, and
the barrier layers comprise a two-dimensional insulating material.

7. The semiconductor device of claim 6, wherein each of the barrier layers comprises one to three layers of boron nitride (BN).

8. The semiconductor device of claim 1, wherein a bandgap energy of the barrier layers along the second direction is greater than a bandgap energy of the tunneling layer, a bandgap energy of the charge trap layers, and a bandgap energy of the blocking layer.

9. The semiconductor device of claim 1, wherein a thickness of each of the barrier layers ranges from 0.3 nm to 1 nm.

10. The semiconductor device of claim 1, wherein a thickness of the charge storage structure ranges from 4 nm to 8 nm.

11. The semiconductor device of claim 1, wherein a thickness of the first region is greater than a thickness of the third region.

12. A semiconductor device comprising:
a plate layer;
gate electrodes stacked on the plate layer, the gate electrodes spaced apart from each other in a first direction, the first direction being perpendicular to an upper surface of the plate layer, the gate electrodes including channel holes passing therethrough and extending in the first direction; and
channel structures in the channel holes, each of the channel structures including a blocking layer, a charge storage structure, a tunneling layer, and a channel layer that are sequentially arranged from the gate electrodes in a second direction, the second direction being perpendicular to the first direction,
wherein the charge storage structure has a first region adjacent to the tunneling layer and a second region between the first region and the blocking layer,
wherein the charge storage structure includes charge trap layers and barrier layers between the charge trap layers, the charge trap layers including silicon nitride, the barriers layers including a two-dimensional insulating material, and
wherein the barrier layers are arranged at a first density in the first region and at a second density in the second region, the second density being lower that the first density.

13. The semiconductor device of claim 12, wherein a bandgap energy of the barrier layers is greater than 10 eV along the second direction.

14. The semiconductor device of claim 12, wherein a bandgap energy of the barrier layers is greater than a bandgap energy of the charge trap layers and a bandgap energy of the tunneling layer.

15. The semiconductor device of claim 12, wherein a bandgap energy of the barrier layers is greater than a bandgap energy of the blocking layer.

16. The semiconductor device of claim 12, wherein the barrier layers each have a first thickness in the first region and a second thickness in the second region, the second thickness being less than the first thickness.

17. The semiconductor device of claim 12, wherein
the barrier layers each have a same thickness in the first region and in the second region, and
the barrier layers are arranged at a first separation distance in the first region and at a second separation distance is the second region, the first separation distance being different from the second separation distance.

18. The semiconductor device of claim 12, wherein
the charge storage structure further comprises a third region between the second region and the blocking layer, and
the barrier layers are arranged at a third density in the third region, the third density being lower than the second density.

19. A data storage system comprising:
a semiconductor storage device including a first semiconductor structure including circuit elements, a second semiconductor structure on the first semiconductor structure, and an input/output pad electrically connected to the circuit elements; and
a controller electrically connected to the semiconductor storage device through the input/output pad and configured to control the semiconductor storage device,
wherein the second semiconductor structure include
a plate layer,
gate electrodes stacked on the plate layer, the gate electrodes spaced apart from each other in a first direction, the first direction being perpendicular to an upper surface of the plate layer, the gate electrodes including channel holes passing therethrough and extending in the first direction, and
channel structures in the channel holes, each of the channel structures including a blocking layer, a charge storage structure, a tunneling layer, and a channel layer that are sequentially arranged from the gate electrodes in a second direction, the second direction being perpendicular to the first direction,
wherein the charge storage structure has a first region adjacent to the tunneling layer and a second region between the first region and the blocking layer,
wherein the charge storage structure includes charge trap layers and barrier layers between the charge trap layers. the charge trap layers including silicon nitride, the barrier layers including a two-dimensional insulating material, and
wherein the barrier layers are arranged at a first density in the first region and at a second density, in the second region, the second density being lower than the first density.

20. The semiconductor device of claim 19, wherein a bandgap energy of the barrier layers along the second direction is greater than a bandgap energy of the tunneling layer, bandgap energy of the charge trap layers, and a bandgap energy of the blocking layer, respectively.
